(19) United States
(12) Patent Application Publication
(10) Pub. No.: US 2025/0120173 A1
(43) Pub. Date: Apr. 10, 2025

(54) Cascode Semiconductor Devices

(71) Applicant: The Hong Kong University of Science and Technology, Hong Kong (CN)

(72) Inventors: Jing CHEN, Hong Kong (CN); Ji SHU, Hong Kong (CN)

(21) Appl. No.: 18/829,368

(22) Filed: Sep. 10, 2024

Related U.S. Application Data
(60) Provisional application No. 63/589,027, filed on Oct. 10, 2023.

(51) Int. Cl. H01L 27/088; H01L 27/06; H03K 17/0412; H03K 17/0814; H03K 17/16

(52) U.S. Cl. CPC H10D 84/84; H03K 17/08142; H10D 84/811; H03K 17/04123; H03K 17/162; H03K 2217/94047

(57) ABSTRACT

A cascode semiconductor device comprise a normally-on high-voltage (HV) silicon carbide (SiC) junction field-effect transistor (JFET), a normally-off low-voltage (LV) gallium nitride (GaN) high-electron-mobility transistor (HEMT) and a clamping circuit. The SiC JFET has a first gate terminal, a first drain terminal and a first source terminal. The GaN HEMT has a second gate terminal, a second drain terminal and a second source terminal. The second drain terminal is connected to the first source terminal. The second source terminal is connected to the first gate terminal. The clamping circuit is connected between the second drain terminal and the second gate terminal and has a clamping voltage. The clamping voltage is greater than a magnitude of a threshold voltage of the SiC JFET and smaller than a reverse gate voltage limit of the SiC JFET.

### CROSS-REFERENCE TO RELATED APPLICATIONS

This application claims priority to the U.S. provisional patent application Ser. No. 63/589,027, filed Oct. 10, 2023, entitled “Cascode GaN/SiC Device Integrated with a Clamping Circuit for the Gate Protection of SiC JFET”, hereby incorporated herein by reference as to its entirety.

### FIELD OF THE DISCLOSURE

The present disclosure generally relates to semiconductor devices, and more particularly to cascode semiconductor devices.

### BACKGROUND

Any discussion of the prior art throughout the specification should in no way be considered as an admission that such prior art is widely known or forms part of common general knowledge in the field.

Power devices based on wide-bandgap (WBG) semiconductors, such as gallium nitride (GaN) and silicon carbide (SiC), are suitable for the next generation high-efficiency and high-power-density converters, mainly owing to their superior properties than the silicon (Si)-based counterparts, such as higher operation temperature, faster switching speed, and lower specific on-resistance.

SiC-based power devices, such as SiC metal-oxide-semiconductor field-effect transistors (MOSFETs) and SiC junction field-effect transistors (JFETs), have been intensively developed, targeting at applications of high voltage levels. For SiC MOSFETs, the high trap density at the silicon dioxide (SiO₂)/SiC interface of the gate oxide reduces the channel mobility significantly, thus increasing the channel resistance and conduction loss. SiC JFET does not suffer from the high channel resistance issue, but its depletion-mode (D-mode) gate control is not desirable in power electronics applications that demand fail-safe operation.

### SUMMARY

According to embodiments of the present disclosure, a cascode semiconductor device comprises a normally-on high-voltage (HV) silicon carbide (SiC) junction field-effect transistor (JFET), a normally-off low-voltage (LV) gallium nitride (GaN) high-electron-mobility transistor (HEMT) and a clamping circuit. The SiC JFET has a first gate terminal, a first drain terminal and a first source terminal. The GaN HEMT has a second gate terminal, a second drain terminal and a second source terminal. The second drain terminal is connected to the first source terminal. The second source terminal is connected to the first gate terminal. The clamping circuit is connected between the second drain terminal and the second gate terminal and has a clamping voltage. The clamping voltage is greater than a magnitude of a threshold voltage of the SiC JFET and smaller than a reverse gate voltage limit of the SiC JFET.

According to certain embodiments, the GaN HEMT and the SiC JFET have a substantially same current rating.

According to certain embodiments, the SiC JFET has a substantially higher rated blocking voltage than the GaN HEMT.

According to certain embodiments, the clamping circuit is monolithically integrated with the GaN HEMT.

According to certain embodiments, the clamping circuit comprises a plurality of diodes that are connected in series.

According to certain embodiments, the clamping circuit comprises a plurality of lateral field-effect rectifiers (L-FERs) that are connected in series. In some embodiments, each of the plurality of L-FERs is implemented by binding gate contact and source contact of another LV GaN HEMT. The number of the plurality of L-FERs may be based on the clamping voltage.

According to certain embodiments, the clamping circuit comprises a bi-directional Zener diode.

According to certain embodiments, the clamping circuit comprises a Zener diode connected in series with a diode.

According to certain embodiments, the diode is selected from a group consisting of a PN diode, a Schottky barrier diode, and a lateral field-effect rectifier. In some embodiments, the diode can be implemented by a connection of a source terminal and a gate terminal of another LV GaN HEMT.

According to certain embodiments, the clamping voltage is greater than 7V and smaller than 30V.

According to embodiments of the present disclosure, a cascode semiconductor circuit comprise a cascode semiconductor device and a drive circuit connected between the second gate terminal and the second source terminal of the GaN HEMT for applying a gate signal to the second gate terminal.

According to certain embodiments, the gate-source voltage of the SiC JFET is clamped below 30V.

According to embodiments of the present disclosure, a method of operating the cascode semiconductor device comprises: applying, by the drive circuit, a turn-off signal to the second gate terminal of the GaN HEMT, and in response to the turn-off signal, current flowing through the GaN HEMT being diverted into an output capacitance connected between the second drain terminal and the second source terminal of the GaN HEMT.

According to certain embodiments, the method further comprises in response to the turn-off signal, current flowing through SiC JFET is diverted into a capacitance connected between the first gate terminal and the first drain terminal of the SiC JFET, thereby increasing voltage between the first drain terminal and the second source terminal.

According to certain embodiments, the method further comprises in response to the turn-off signal, if a voltage between the second drain terminal and the second source terminal exceeds the clamping voltage, a current flows into the second gate terminal of the GaN HEMT through the clamping circuit.

According to certain embodiments, the method further comprises in response to the turn-off signal, a voltage at the second gate terminal of the GaN HEMT increases, thereby improving channel conductivity of the GaN HEMT.

According to certain embodiments, the method further comprises in response to the turn-off signal, part of the current flows through the channel of the GaN HEMT and stored charges in the output capacitance of the GaN HEMT are discharged, thereby suppressing drain-source overvoltage of the GaN HEMT.

Other example embodiments are discussed herein.

### BRIEF DESCRIPTION OF THE DRAWINGS

The detailed description is set forth with reference to the accompanying drawings. The drawings are provided for purposes of illustration only and merely depict example embodiments of the present disclosure. The drawings are provided to facilitate understanding of the present disclosure and shall not be deemed to limit the breadth, scope, or applicability of the present disclosure. The drawings are not to scale, unless otherwise stated. Certain parts of the drawings may be exaggerated for explanation purposes and shall not be considered limiting unless otherwise specified.

FIG. 1 illustrates a cascode semiconductor device according to certain embodiments of the present disclosure.

FIG. 2 illustrates a first specific implementation of the cascode semiconductor device of FIG. 1, where the clamping circuit comprises a plurality of diodes.

FIG. 3 illustrates a second specific implementation of the cascode semiconductor device of FIG. 1, where the clamping circuit comprises a plurality of lateral field-effect rectifiers (L-FERs).

FIG. 4 illustrates a third specific implementation of the cascode semiconductor device of FIG. 1, where the clamping circuit comprises a bi-directional Zener diode.

FIG. 5 illustrates a fourth specific implementation of the cascode semiconductor device of FIG. 1, where the clamping circuit comprises a Zener diode connected in series with a diode, and the diode can be a PN diode, a Schottky-barrier diode, or a L-FER.

FIG. 6 illustrates a cascode semiconductor circuit according to certain embodiments of the present disclosure.

FIG. 7 illustrates a method of operating a cascode semiconductor device according to certain embodiments of the present disclosure.

FIG. 8A illustrates the first stage (stage 1) of the operation principle of a cascode semiconductor device according to certain embodiments of the present disclosure.

FIG. 8B illustrates the second stage (stage 2) of the operation principle of the cascode semiconductor device of FIG. 8A.

FIG. 9 illustrates a test circuit for characterizing the switching process of cascode semiconductor devices with and without a clamping circuit according to certain embodiments of the present disclosure.

FIG. 10A shows V_{DS}˜time curves of a cascode semiconductor device without a clamping circuit under I_{D}=8 A and 24 A respectively during its turning-off process according to certain embodiments of the present disclosure.

FIG. 10B shows I_{DS}˜time curves of the cascode semiconductor device of FIG. 10A under I_{D}=8 A and 24 A respectively during its turning-off process.

FIG. 10C shows −V_{GS-JFET}˜time curves of the cascode semiconductor device of FIG. 10A under I_{D}=8 A and 24 A respectively during its turning-off process.

FIG. 11A shows V_{DS}˜time curves of a cascode semiconductor device with a clamping circuit under I_{D}=8 A and 24 A respectively during its turning-off process according to certain embodiments of the present disclosure.

FIG. 11B shows I_{DS}˜time curves of the cascode semiconductor device of FIG. 11A under I_{D}=8 A and 24 A respectively during its turning-off process.

FIG. 11C shows −V_{GS-JFET}˜time curves of the cascode semiconductor device of FIG. 11A under I_{D}=8 A and 24 A respectively during its turning-off process.

### DETAILED DESCRIPTION

The present disclosure will now be described with reference to the following examples which should be considered in all respects as illustrative and non-restrictive.

Throughout the description and the claims, the words “comprise”, “comprising”, and the like are to be construed in an inclusive sense as opposed to an exclusive or exhaustive sense; that is to say, in the sense of “including, but not limited to”.

Furthermore, as used herein and unless otherwise specified, the use of the ordinal adjectives “first”, “second”, etc., to describe a common object, merely indicate that different instances of like objects are being referred to, and are not intended to imply that the objects so described must be in a given sequence, either temporally, spatially, in ranking, or in any other manner.

Example embodiments relate to cascode semiconductor devices, circuits, and methods thereof.

Combining a low-voltage (LV) enhancement-mode (E-mode) Si MOSFET with a high-voltage (HV) depletion-mode (D-mode) SiC JFET in a cascode Si/SiC configuration can realize an HV E-mode power device with low conduction loss. Further, GaN E-mode high-electron-mobility transistors (HEMTs) have been widely available and commercialized with products at both low- and medium-voltage levels ranging from 15V to 400V. The merits of an LV E-mode GaN HEMT and an HV D-mode SiC JFET can be combined to realise a HV cascode GaN/SiC device. Compared with the cascode Si/SiC device, the LV Si MOSFET is replaced by an LV GaN HEMT. This brings in the benefits of faster switching speed, higher operating temperature, thermally stable threshold voltage (V_{TH}), and zero reverse-recovery charge (Qᵣᵣ).

However, replacing the LV Si MOSFET with an LV GaN HEMT may lead to challenging issues. These issues comprise the gate overstress of the HV SiC JFET during the switching process. Due to the lack of avalanche capability in the LV GaN HEMT, the drain-source voltage of GaN HEMT (V_{DS-HEMT}) cannot be clamped during the switching process. As a result, the gate of the HV SiC JFET may be overstressed because the gate-source voltage of SiC JFET (V_{GS-JFET}) equals to V_{DS-HEMT} with a reverse polarity. In comparison, the JFET's gate in the cascode Si/SiC device is protected against overstress, since the V_{GS-JFET} can be clamped by the LV Si MOSFET with avalanche capability.

To protect the gate of HV SiC JFET in the cascode GaN/SiC device, a flip-chip co-packaging structure can be employed to reduce the parasitic interconnection inductance between the SiC JFET and GaN HEMT to suppress the oscillation and also decrease the magnitude of V_{DS-HEMT} during the switching process. However, in addition to the parasitic inductance, the capacitance mismatch between the HV JFET and LV HEMT can also lead to V_{DS-HEMT} overshoot and the associated gate overstress of JFET. As a result, a Zener diode (ZD) can be used for reliable V_{DS-HEMT} clamping, thereby protecting the SiC JFET from gate overstress even after co-packaging. ZD is a heavily doped Si PN-junction with a forward turn-on voltage of ˜0.7V, which is lower than the reverse-conduction turn-on voltage of a GaN HEMT. Therefore, during the reverse-conduction phase of the cascode GaN/SiC device, current flows through the forward-biased Si PN-junction of the ZD. As a result, when the cascode device switches from the reverse-conduction mode to the forward-blocking mode, the ZD experiences a reverse-recovery process to sweep out the excess minority carriers in the Si PN-junction, leading to a prolonged switching process with exacerbated switching loss.

Example embodiments overcome or ameliorate at least one of the disadvantages of the prior art by providing new structural designs with improved device performance.

Example embodiments comprise a cascode semiconductor device that comprises a GaN/SiC device integrated with a clamping circuit. According to one or more embodiments, the gate of the SiC JFET can be protected against overstress without compromising the switching performance of the cascode GaN/SiC device.

According to one or more embodiments, a cascode semiconductor device comprises a cascode GaN/SiC power device integrated with a clamping circuit for protecting the SiC JFET from gate overstress during the switching process. The cascode GaN/SiC power device comprises a HV normally-on SiC JFET, a LV normally-off GaN HEMT, and a clamping circuit. The gate and source of the HV SiC JFET are connected to the source and drain of the LV GaN HEMT respectively. The clamping circuit is electrically disposed between the drain and gate of the LV GaN HEMT. The gate and source of the LV GaN HEMT are the gate and source of the cascode GaN/SiC device respectively, and the drain of the HV SiC JFET is the drain of the cascode GaN/SiC device. The integrated clamping circuit can clamp or suppress the drain-source overvoltage of the LV GaN HEMT during the switching process, thereby protecting the HV SiC JFET from gate overstress.

One or more embodiments comprise a cascode semiconductor device that comprises a SiC JFET, a GaN HEMT, and a clamping circuit. The gate and source of the SiC JFET are connected to the source and drain of the GaN HEMT respectively such that a current path is formed through the SiC JFET and the GaN HEMT. The clamping circuit is connected between the drain and gate of the GaN HEMT. The SiC JFET can be protected from gate overstress without compromising the switching performance of the cascode GaN/SiC device. With the clamping circuit, the SiC JFET's gate voltage can be effectively clamped, thereby protecting the SiC JFET against gate overstress during the switching process. Compared with the abovementioned ZD-protection solution, the reverse-conduction current of the cascode semiconductor device flows through the GaN HEMT, which exhibits zero Qᵣᵣ when operated in the reverse-conduction mode. As a result, the revere-recovery performance of the cascode semiconductor device is not compromised since no Qᵣᵣ is introduced. In addition, the parasitic capacitance of the clamping circuit can be very small as the clamping circuit only needs to conduct a small current of several amperes for a short switching transient duration of less than a few hundred nanoseconds. As a result, the switching speed of the cascode semiconductor device will not be affected noticeably.

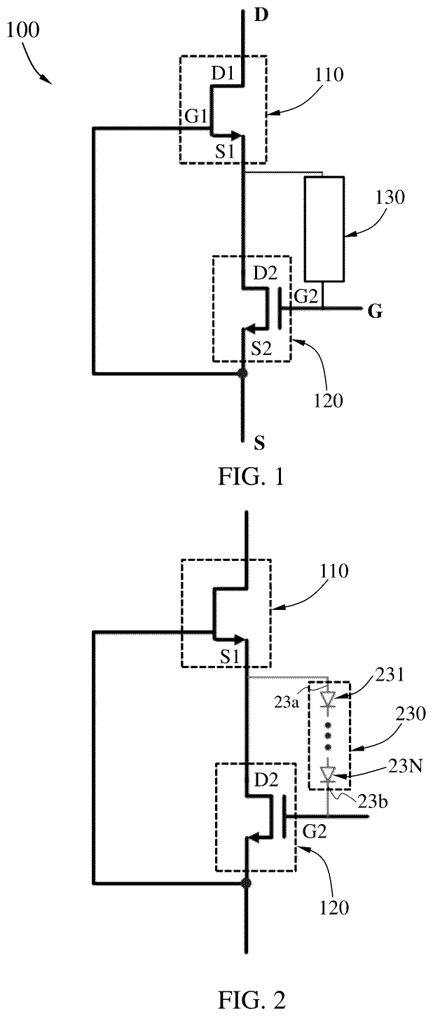

FIG. 1 illustrates a cascode semiconductor device 100 according to certain embodiments of the present disclosure. The cascode semiconductor device 100 comprises a normally-on HV SiC JFET 110, a normally-off LV GaN HEMT 120, and a clamping circuit 130.

The SiC JFET 110 comprises a first gate terminal G1, a first drain terminal D1 and a first source terminal Si. The LV GaN HEMT 120 comprises a second gate terminal G2, a second drain terminal D2 and a second source terminal S2. The second drain terminal D2 is connected to the first source terminal Si, and the second source terminal S2 is connected to the first gate terminal G1.

The clamping circuit 130 is connected between the second drain terminal D2 (which is connected to the first source terminal Si) and the second gate terminal G2. The clamping circuit 130 has a clamping voltage. The clamping voltage is greater than a magnitude of a threshold voltage (V_{TH}) of the SiC JFET and lower than a reverse gate voltage limit of the SiC JFET.

The threshold voltage is a critical parameter that defines the gate-source voltage at which the transistor starts to turn off. For the normally-on SiC JFET, the threshold voltage is typically negative. This means that a negative gate-source voltage is required to turn the device off. The exact value of V_{T}H can vary depending on the specific device and manufacturer, but it may be commonly in the range of −2V to −30V. The magnitude of a threshold voltage is its absolute value, namely |V_{TH}|.

The reverse gate voltage limit of the normally-on SiC JFET specifies the maximum allowable negative gate-source voltage that can be applied without damaging the device. This parameter is crucial for ensuring the device's reliability and longevity. As an example, the reverse gate voltage limit for SiC JFETs may be around 30V. In some embodiments, the clamping voltage can be greater than 7V and smaller than 30V. In some embodiments, the clamping voltage may be other values depending on specific applications in which the devices are used.

In some embodiments, the GaN HEMT 120 and the SiC JFET 110 have a substantially same (such as same or similar) current rating. The current rating specifies the maximum amount of continuous drain current that the device can handle without suffering damage or performance degradation. The current rating may depend on the specific device, its application conditions and its manufacturer. For example, the current rating for the GaN HEMT 120 and the SiC JFET 110 may be in the range of 1 A to 100 A. Having substantially the same current rating for the GaN HEMT 120 and the SiC JFET 110 in the cascode device optimizes performance, improves reliability, and simplifies design. This balanced approach leverages the strengths of both materials—GaN for high-speed switching and SiC for high-voltage handling—while suppressing overstress for both transistors, leading to enhanced overall device efficiency and longevity.

In some embodiments, the SiC JFET 110 can have a substantially higher rated blocking voltage than the GaN HEMT 120. The rated blocking voltage is the maximum voltage that the device can withstand in the OFF state without experiencing breakdown. This parameter is crucial for ensuring that the device can handle the high voltage conditions in various power electronic applications. In some embodiments, the rated blocking voltage for the SiC JFET 110 is in the range of 200V to 3000V, and the rated blocking voltage for the GaN HEMT 120 is in the range of 10V to 50V, which is substantially lower than the rated blocking voltage for the SiC JFET 110.

This design offers several significant benefits. The SiC JFET, with its higher blocking voltage, can handle much higher voltages compared to the GaN HEMT. This allows the cascode device to operate effectively in high-voltage applications while maintaining safety and reliability. The GaN HEMT is protected from high voltages due to the higher blocking voltage of the SiC JFET. This reduces the voltage stress on the GaN HEMT, allowing it to focus on its strengths—high-speed switching. As a result, this enhances the device's ability to handle high voltages while leveraging the GaN HEMT's high-speed switching capabilities. This results in improved efficiency, reliability, and flexibility in high-voltage and high-frequency applications, making the cascode device highly effective for modern power electronics and switching applications.

In some embodiments, the clamping circuit 130 can be formed as a standalone block, which is separate from the SiC JFET 110 and/or the GaN HEMT 120. In some embodiments, the clamping circuit 130 can be monolithically integrated with the GaN HEMT 120. That is, during manufacturing, the clamping circuit 130 and the GaN HEMT 120 are fabricated together on a same semiconductor substrate. This can be achieved by using advanced semiconductor manufacturing techniques to integrate different elements in a cohesive manner. This integration allows both the clamping circuit and the GaN HEMT to function as a single, unified device rather than as separate components. Accordingly, this results in a compact device arrangement with improved performance, such as faster response time and better protection against transient events.

The cascode semiconductor device 100 can be considered as a three-terminal device having a gate terminal G, a drain terminal D and a source terminal S. As shown in FIG. 1, the first drain terminal D1, the second source terminal S2 and the second gate terminal G2 act as the drain terminal D, the source terminal S and the gate terminal G of the cascode semiconductor device 100 respectively. The cascode semiconductor device 100 can be driven to turn ON or OFF by applying a drive signal, such as a voltage, to the gate terminal G. In some embodiments, the combination of the SiC JFET 110 and the GaN HEMT 120 are called a cascode GaN/SiC device, and thereby the cascode semiconductor device 100 comprises the cascode GaN/SiC device and the clamping circuit.

The clamping circuit can be realised by a variety of implementations with some examples shown in FIG. 2 to FIG. 5 as detailed below.

As shown in FIG. 2, the clamping circuit 230 comprises a plurality of diodes 231 . . . 23N that are connected in series. N is an integer and greater than 1. That is, the total number of the diodes is N. The plurality of diodes forms a diode chain starting from the first diode 231 and ends with the last diode 23N. The anode 23a of the diode 231 is connected to the second drain terminal D2 of the GaN HEMT 120 (or the first source terminal S1 of the SiC JFET 110 as the terminals D2 and S1 are connected). The cathode 23b of the diode 23N is connected to the second gate terminal G2 of the GaN HEMT 120. Each diode can be a PN diode, such as a Si PN diode or a GaN PN diode. Implementing the plurality of diodes as GaN PN diodes is preferred as this will be compatible with the GaN HEMT during device fabrication.

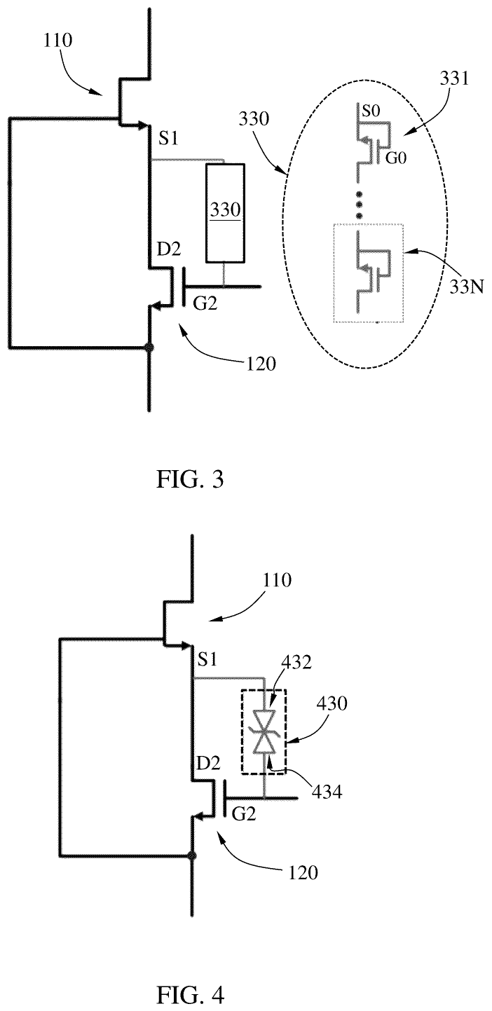

As shown in FIG. 3, the clamping circuit 330 comprises a plurality of lateral field-effect rectifiers (L-FERs) 331 . . . 33N that are connected in series. N is an integer and greater than 1. That is, the total number of the L-FERs is N. The plurality of L-FERs forms a L-FER chain starting from the first L-FER 331 and ends with the last L-FER 33N. For the first L-FER 331, both its source and gate terminals are connected to the second drain terminal D2 of the GaN HEMT 120 (or the first source terminal S1 of SiC JFET 110). For the last L-FER 33N, its drain terminal is connected to the second gate terminal G2 of the GaN HEMT 120.

The L-FERs combine features of both field-effect transistors and rectifiers, making them suitable for specific applications where both high-speed switching and rectification are required. Each L-FER can be realized or formed or implemented by binding the gate and source contacts of a LV GaN HEMT to form the anode terminal, as illustrated in FIG. 3. Take the first L-FER 331 as an example. It is implemented by binding the gate terminal or contact G0 and the source terminal or contact S0 of the LV GaN HEMT, which may have same or different electrical properties compared to the LV GaN HEMT 120 according to practice needs. The LV GaN HEMTs for forming the plurality of L-FERs may be same or different in their geometric dimensions and/or electrical properties according to practical needs. The clamping circuit can be a standalone block or monolithically integrated with the GaN HEMT 120. The parasitic capacitance of the clamping circuit can be designed to be negligible as the circuit only needs to conduct a small current into the gate terminal of the GaN HEMT during the turn-off transient. The number of the series-connected L-FERs in the clamping circuit can be determined by or based on the target clamping voltage that can be predetermined or preset. The clamping voltage can be greater than the magnitude of the SiC JFET's V_{TH}, such as 7V, to ensure the cascode device can be turned OFF during the switching process. Further, the clamping voltage can be lower than the reverse gate voltage limit of the SiC JFET, such as 30V, to protect the SiC JFET from gate overstress.

As shown in FIG. 4, the clamping circuit 430 comprises a bi-directional Zener diode. The bi-directional Zener diode comprises two Zener diodes 432 and 434 that are connected in series but oriented in opposite directions. The anode of the Zener diode 432 is connected to the second drain terminal D2 of the GaN HEMT 120 (or the first source terminal S1 of the SiC JFET 110). The anode of the Zener diode 434 is connected to the second gate terminal G2 of the GaN HEMT 120. The bi-directional Zener diode provides protection against voltage spikes in both positive and negative directions, such that the device can clamp excessive voltages in both polarities, preventing damage from both positive and negative transients.

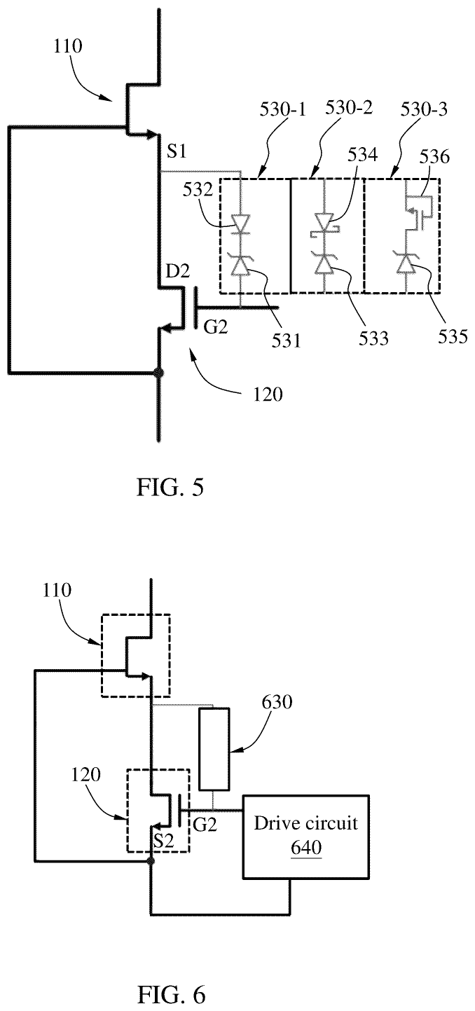

As shown in FIG. 5, the clamping circuit can be a clamping circuit 530-1, a clamping circuit 530-2, or a clamping circuit 530-3. The clamping circuit 530-1 comprises a Zener diode 531 connected in series with a PN diode 532. The clamping circuit 530-2 comprises a Zener diode 533 connected in series with a Schottky barrier diode 534. The clamping circuit 530-3 comprises a Zener diode 535 connected in series with a lateral field-effect rectifier 536. The anodes of the Zener diodes 531, 533 and 535 are connected to the second gate terminal G2 of the GaN HEMT 120. The anodes of the PN diode 532, the Schottky barrier diode 534 and the lateral field-effect rectifier 536 are connected to the second drain terminal D2 of the GaN HEMT 120 (or the first source terminal Si of the SiC JFET 110). In this embodiment, the lateral field-effect rectifier 536 is illustrated as being realised by binding the gate and source contacts of a LV GaN HEMT (which is not the GaN HEMT 120) to form the anode terminal.

FIG. 6 illustrates a cascode semiconductor circuit according to certain embodiments of the present disclosure. The cascode semiconductor circuit comprise a cascode semiconductor device and a drive circuit 640. The cascode semiconductor device can be any of the cascode semiconductor devices as described above with reference to one or more figures. For example, the cascode semiconductor device comprises the normally-on HV SiC JFET 110, the normally-off LV GaN HEMT 120, and a clamping circuit 630. The clamping circuit 630 can be any of the clamping circuits as described above with reference to one or more figures. The drive circuit 640 is connected between the second gate terminal G2 and the second source terminal S2 of the GaN HEMT 120 for applying a drive signal or gate signal to the second gate terminal G2. The drive circuit is a circuit that generates the gate signal. The gate signal comprises one or more signals for driving the cascode semiconductor device. For example, the gate signal may comprise a turn-off signal to switch off the cascode semiconductor device. For example, the gate signal may comprise a turn-on signal to switch on the cascode semiconductor device. The gate signal may comprise one or more voltage signals.

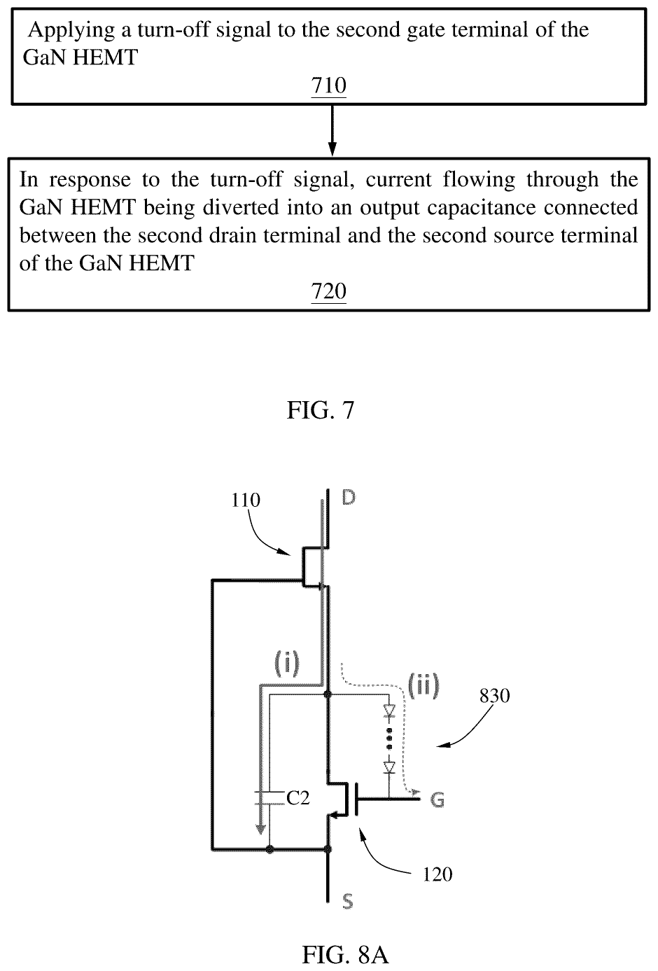

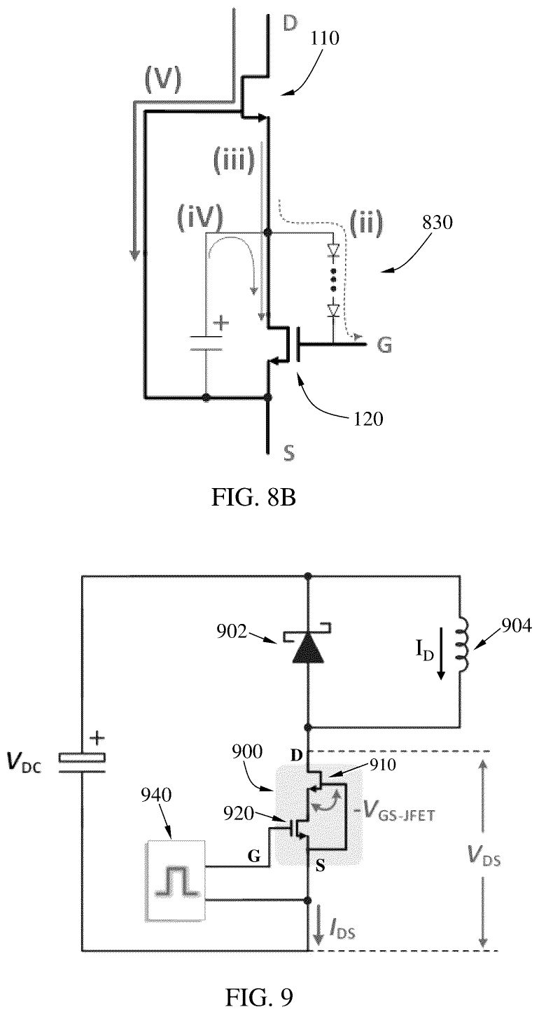

Referring to FIGS. 7, 8A and 8B, methods of operating a cascode semiconductor device are illustrated according to certain embodiments of the present disclosure. The cascode semiconductor device can be any of the cascode semiconductor devices as described above with reference to FIGS. 1 to 6. One or more of the methods, for example, can be implemented by the cascode semiconductor circuit of FIG. 6, or by a circuit comprising the cascode semiconductor circuit of FIG. 6.

Referring to FIG. 7, at block 710, a turn-off signal is applied to the second gate of the GaN HEMT. The GaN HEMT can be any one of the GaN HEMT 120 as described above with reference to one or more figures. The turn-off signal can be a voltage signal that turns off the GaN HEMT. In some embodiments, the turn-off signal can be a termination of applying a voltage signal to the second gate of the GaN HEMT, thereby switching off the GaN HEMT.

At block 720, in response to the turn-off signal, current flowing through the GaN HEMT is diverted into an output capacitance connected between the second drain terminal and the second source terminal of the GaN HEMT. This will be further described below by way of example referring to FIGS. 8A and 8B.

As a result of the turn-off signal, the GaN HEMT 120 is turned-off and enters the saturation region. Current will be diverted into an output capacitance C2 disposed between the second drain and source terminals of the GaN HEMT 120 (see process (i) in FIG. 8A). The output capacitance C2 is the parasitic capacitance created during fabrication of the GaN HEMT 120. As a result, the drain-source voltage (V_{DS-HEMT}) of the GaN HEMT 120 will be increased. The SiC JFET 110 is then pinched off. After that, the current will be diverted into the gate-drain capacitance (not shown) of the SiC JFET 110, and the drain-source voltage of the cascode GaN/SiC device will increase and block the current (see process (V) in FIG. 8B). During the turn-off process, if the V_{DS-HEMT} exceeds the clamping voltage of the clamping circuit 830, a small current will be injected into the second gate terminal of the GaN HEMT 120 through the clamping circuit 830 (see process (ii) in FIGS. 8A and 8B). As a result, the gate voltage of the GaN HEMT 120, which is in the saturation region, will be increased slightly, and accordingly the channel of the GaN HEMT 120 will be more conductive. Therefore, part of the current can flow through the channel of the GaN HEMT 120 instead of charging up the output capacitance C2 of the GaN HEMT 120 (see process (iii) in FIG. 8B), and stored charge in the output capacitance of the GaN HEMT can also be discharged (see process (iV) in FIG. 8B). Such a turn-off process of the cascode GaN/SiC device suppresses the drain-source overvoltage of the GaN HEMT 120, thereby providing protection for the SiC JFET against gate overstress.

In FIGS. 8A and 8B, the clamping circuit 830 comprises a plurality of diodes that are connected in series. It will be understood that this is for illustrative purpose only and the clamping circuit can be implemented differently, including but not limited to, any one of the clamping circuits as described above with reference to FIGS. 3 to 5.

FIG. 9 illustrates a test circuit for characterizing the switching process of cascode semiconductor devices with and without a clamping circuit according to certain embodiments of the present disclosure. The devices under test (DUT) is a 1200V/30 A cascode GaN/SiC device built with the SPICE simulation models of commercial devices.

The test circuit comprises a power supply with a rated voltage V_{DC}, a cascode semiconductor device 900, a drive circuit 940 for driving the cascode semiconductor device 900, a Schottky barrier diode 902, and a load in the form of a resistor 904. The cascode semiconductor device 900 comprises a HV SiC JFET 910 and a LV GaN HEMT 920. The source terminal of the SiC JFET 910 is connected to the drain terminal the GaN HEMT 920 to form a current path. The drain terminal D, the source terminal S, and the gate terminal G of the cascode semiconductor device 900, as well as the drain-source voltage V_{DS}, the drain-source current I_{DS}, the gate-source voltage (V_{GS-JFET}) of the SiC JFET 910 and the load current I_{D} are also shown in FIG. 9. For purpose of comparison, some cascode semiconductor devices each comprises a clamping circuit as described above with reference to any one of FIGS. 1 to 5, while other cascode semiconductor devices each does not comprise any clamping circuit.

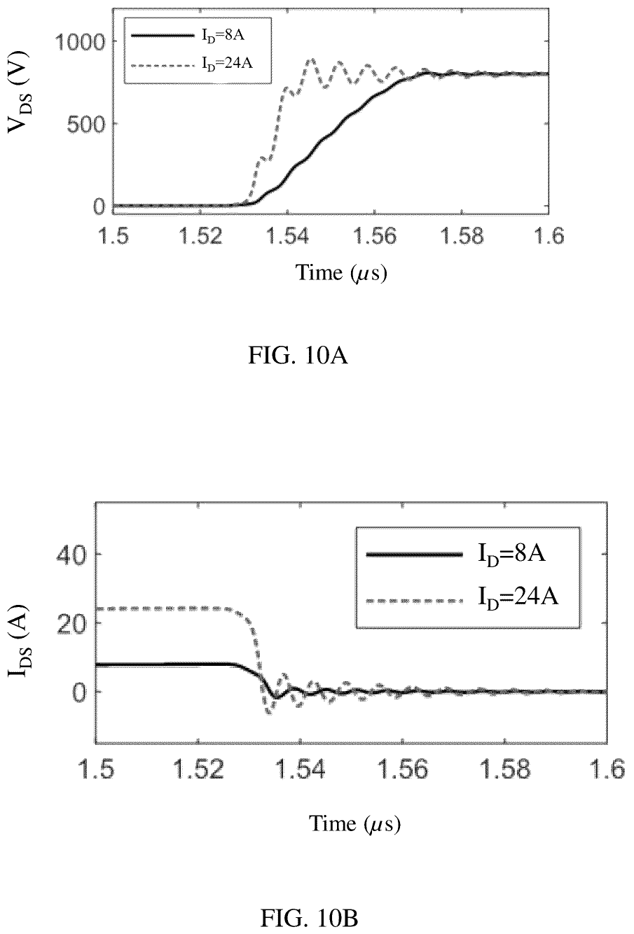

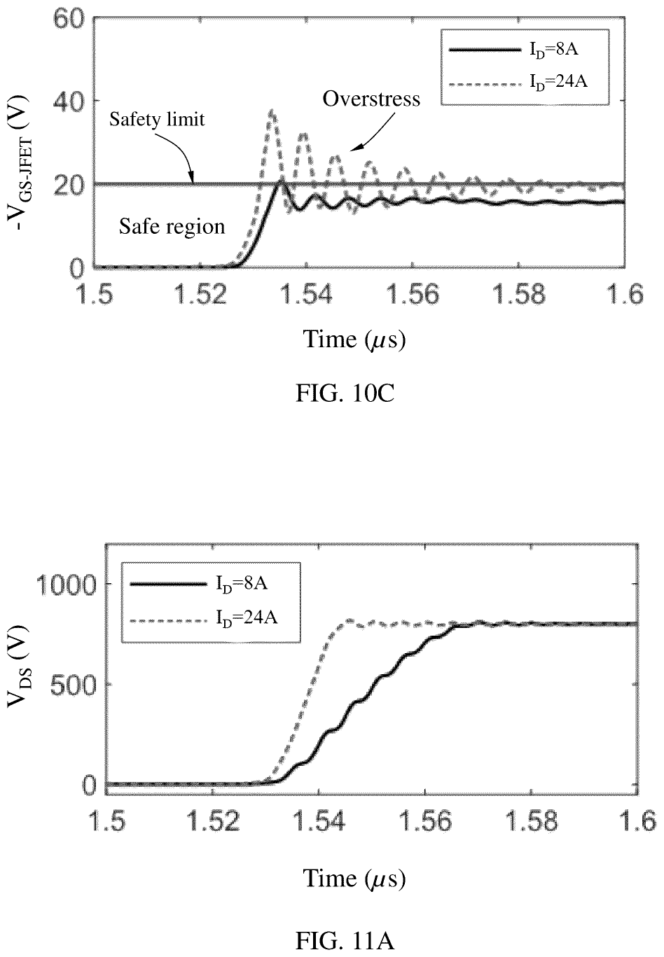

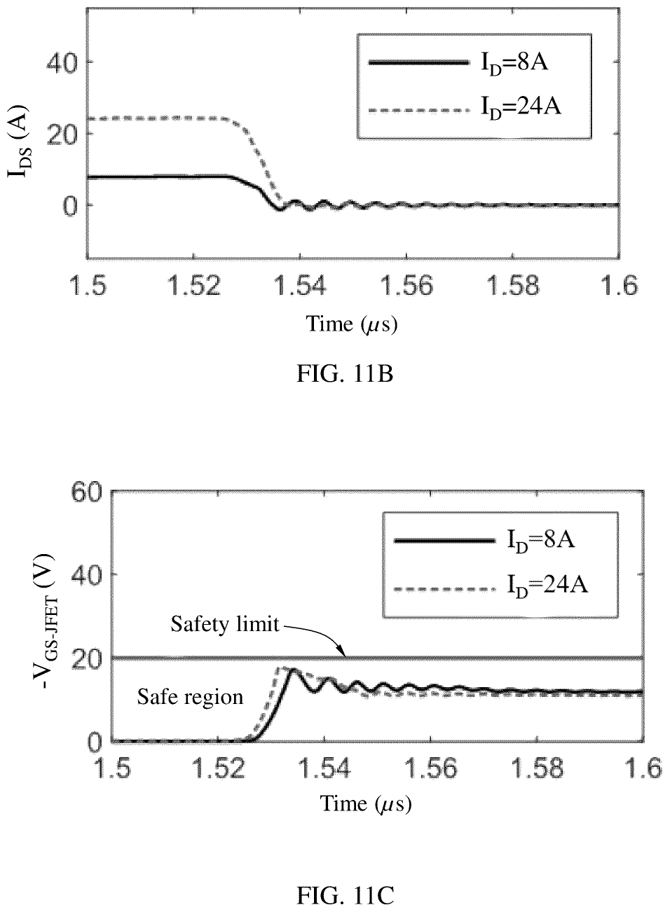

The test results for the cascode semiconductor devices that do not comprise any clamping circuit are shown in FIGS. 10A to 10C. The test results for the cascode semiconductor devices that comprise clamping circuits are shown in FIGS. 11A to 11C.

As can be seen, without the clamping circuit, the gate voltage of the SiC JFET (V_{GS-JFET}) exceeds the safety limit during the turn-off process, thereby overstressing the gate of the SiC JFET. In addition, there are much noticeable oscillations for V_{DS}, I_{DS} and V_{GS-JFET} under larger load current.

In comparison, with the clamping circuit, the gate voltage of JFET is well clamped within the safe region (i.e., the region below the safety limit), thereby providing protection for JFET's gate. Additionally, the switching process oscillation is also significantly suppressed with the clamping circuit, which is favourable in power electronics system.

According to embodiments above, one or more cascode semiconductor devices, circuits, and methods thereof are provided. By incorporating clamping circuits, the cascode semiconductor devices or circuits can mitigate or avoid gate overstress of the HV SiC JFET and in the meanwhile do not compromise the switching performance. This is advantageous particularly in applications where high voltage and fast speeding are required.

According to one or more embodiments, the clamping circuit can be monolithically integrated with the GaN HEMT. For example, when the camping circuit comprises a plurality of diodes that are connected in series, or a plurality of lateral field-effect rectifiers (L-FERs) that are connected in series, as described and illustrated above, the camping circuit and the GaN HEMT can be fabricated together on a same semiconductor substrate. This offers a plurality of technical advantages. For example, this monolithic integration reduces parasitic inductances and resistances associated with external wiring and packaging, leading to improved switching performance and efficiency. The lower parasitic elements enable faster switching speeds, which is advantageous particularly in high-frequency applications. As another example, the monolithic integration allows for a more compact design, reducing the overall size and weight of the power module. This is advantageous particularly in applications where space and weight are critical factors. The integration also reduces the number of discrete components needed, lowering assembly and material costs. Fewer components mean a lower probability of failure and reduced maintenance requirements, further driving down long-term costs. Additionally, the monolithically integrated solution simplifies the design process as the clamping circuit is already built into the device, reducing the need for additional design steps and verifications.

The present inventors have further recognized that when the clamping circuit comprises one or more Zener diodes, it cannot be monolithically integrated with the GaN HEMT of the cascode GaN/SiC device as the Zener diode cannot be realized with GaN material at this stage. As such, the skilled person will appreciate some embodiments are preferrable to others after reading the present disclosure.

It will be further appreciated that the clamping circuits as described above are illustrative. Modifications or variations to the described clamping circuits are possible and still within the concept of the present disclosure.

As used herein, the term “high-voltage”, “high voltage” or “HV” refers to a breakdown voltage of 400V or above.

As used herein, the term “low-voltage”, “low voltage” or “LV” refers to a breakdown voltage between 30V to 60V inclusive of both ends.

As used herein, the term “connected” or “connecting” refers to electrical connection.

As used herein, a “channel” of a field-effect transistor refers to the pathway or region through which charge carriers (electrons or holes) flow from the source terminal to the drain terminal of the transistor when the transistor is in operation. The conductivity of this pathway or region is controlled by the voltage applied to the gate terminal of the transistor.

As used herein, the term “standalone block” refers to a self-contained module or functional unit that is formed separately and independently.

It will further be appreciated that any of the features in the above embodiments of the disclosure may be combined together and are not necessarily applied in isolation from each other. Similar combinations of two or more features from the above described embodiments or preferred forms of the disclosure can be readily made by one skilled in the art.

Unless otherwise defined, the technical and scientific terms used herein have the plain meanings as commonly understood by those skill in the art to which the example embodiments pertain. It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

What is claimed is:

1. A cascode semiconductor device comprising:
a normally-on high-voltage (HV) silicon carbide (SiC) junction field-effect transistor (JFET) having a first gate terminal, a first drain terminal and a first source terminal;
a normally-off low-voltage (LV) gallium nitride (GaN) high-electron-mobility transistor (HEMT) having a second gate terminal, a second drain terminal and a second source terminal, the second drain terminal being connected to the first source terminal, the second source terminal being connected to the first gate terminal; and
a clamping circuit connected between the second drain terminal and the second gate terminal and having a clamping voltage, the clamping voltage being greater than a magnitude of a threshold voltage of the SiC JFET and smaller than a reverse gate voltage limit of the SiC JFET.

2. The cascode semiconductor device of claim 1, wherein the GaN HEMT and the SiC JFET have a substantially same current rating.

3. The cascode semiconductor device of claim 1, wherein the SiC JFET has a substantially higher rated blocking voltage than the GaN HEMT.

4. The cascode semiconductor device of claim 1, wherein the clamping circuit can be monolithically integrated with the GaN HEMT or a standalone block.

5. The cascode semiconductor device of claim 1, wherein the clamping circuit comprises a plurality of diodes that are connected in series.

6. The cascode semiconductor device of claim 1, wherein the clamping circuit comprises a plurality of lateral field-effect rectifiers (L-FERs) that are connected in series.

7. The cascode semiconductor device of claim 6, wherein each of the plurality of L-FERs is implemented by binding source contact and gate contact of another LV GaN HEMT.

8. The cascode semiconductor device of claim 7, wherein the number of the plurality of L-FERs is based on the clamping voltage.

9. The cascode semiconductor device of claim 1, wherein the clamping circuit comprises a bi-directional Zener diode.

10. The cascode semiconductor device of claim 1, wherein the clamping circuit comprises a Zener diode connected in series with a diode.

11. The cascode semiconductor device of claim 10, wherein the diode is selected from a group consisting of a PN diode, a Schottky barrier diode, and a lateral field-effect rectifier.

12. The cascode semiconductor device of claim 10, wherein the diode can be implemented by a connection of a source terminal and a gate terminal of another LV GaN HEMT.

13. The cascode semiconductor device of claim 1, wherein the clamping voltage is greater than 7V and smaller than 30V.

14. A cascode semiconductor circuit comprising:
a cascode semiconductor device of claim 1; and
a drive circuit connected between the second gate terminal and the second source terminal of the GaN HEMT for applying a gate signal to the second gate terminal.

15. The cascode semiconductor circuit of claim 14, wherein the gate-source voltage of the SiC JFET is clamped below 30V.

16. A method of operating the cascode semiconductor device of claim 14, the method comprising:
applying, by the drive circuit, a turn-off signal to the second gate terminal of the GaN HEMT; and
in response to the turn-off signal, current flowing through the GaN HEMT being diverted into an output capacitance connected between the second drain terminal and the second source terminal of the GaN HEMT.

17. The method of claim 16, further comprising:
in response to the turn-off signal, current flowing through SiC JFET is diverted into a capacitance connected between the first gate terminal and the first drain terminal of the SiC JFET, thereby increasing voltage between the first drain terminal and the second source terminal.

18. The method of claim 17, further comprising:
in response to the turn-off signal, if a voltage between the second drain terminal and the second source terminal exceeds the clamping voltage, a current flows into the second gate terminal of the GaN HEMT through the clamping circuit.

19. The method of claim 18, further comprising:
in response to the turn-off signal, a voltage at the second gate terminal of the GaN HEMT increases, thereby improving channel conductivity of the GaN HEMT.

20. The method of claim 19, further comprising:
in response to the turn-off signal, part of the current flows through the channel of the GaN HEMT and stored charges in the output capacitance of the GaN HEMT are discharged, thereby suppressing drain-source overvoltage of the GaN HEMT.
